(19) United States
(12) Patent Application Publication
(10) Pub. No.: US 2016/0260773 A1
(43) Pub. Date: Sep. 8, 2016

(54) MAGNETORESISTIVE ELEMENT, METHOD OF MANUFACTURING MAGNETORESISTIVE ELEMENT, AND MEMORY DEVICE

(71) Applicant: KABUSHIKI KAISHA TOSHIBA, Tokyo (JP)

(72) Inventors: Eiji KITAGAWA, Yokohama Kanagawa (JP); Minoru AMANO, Sagamihara Kanagawa (JP)

(73) Assignee: KABUSHIKI KAISHA TOSHIBA, Tokyo (JP)

(21) Appl. No.: 14/830,028

(22) Filed: Aug. 19, 2015

Related U.S. Application Data
(60) Provisional application No. 62/128,262, filed on Mar. 4, 2015.

(51) Int. Cl. H01L 27/22; H01L 43/10; H01L 43/12; H01L 43/02

(52) U.S. Cl. CPC H01L 27/228; H01L 43/02; H01L 43/10; H01L 43/12

(57) ABSTRACT

According to one embodiment, a magnetoresistive element includes a first magnetic layer, an insulating layer on the first magnetic layer, a second magnetic layer on the insulating layer, and an aluminum boride layer on the second magnetic layer.

### CROSS-REFERENCE TO RELATED APPLICATIONS

This application claims the benefit of U.S. Provisional Application No. 62/128,262, filed Mar. 4, 2015, the entire contents of which are incorporated herein by reference.

### FIELD

Embodiments described herein relate generally to a magnetoresistive element, a method of manufacturing the magnetoresistive element, and a memory device.

### BACKGROUND

Magnetoresistive elements are used, for example, for a memory cell of a spin transfer torque magnetic random access memory (STT-MRAM), a magnetic head of a hard disk drive (HDD), and the like. In order to realize a high speed read operation in these memory devices, it is necessary to improve the magnetoresistive (MR) ratio of the magnetoresistive element.

There is a method of improving the MR ratio of the magnetoresistive element by using a spin filter effect. In this method, when the magnetoresistive element has a laminated structure of a first magnetic layer, an insulating layer and a second magnetic layer, the first and second magnetic layers are subjected to high-temperature heat treatment to make the first and second magnetic layers crystallized and to form heteroepitaxial bonded interfaces between the first and second magnetic layers and the insulating layer.

However, in crystallization by high-temperature heat treatment, a part of the elements contained in the first and second magnetic layers are diffused into the interfaces of the first and second magnetic layers and the insulating layer, and thus it is difficult to form an excellent bonded interface.

### BRIEF DESCRIPTION OF THE DRAWINGS

FIG. 1 is a diagram showing a magnetoresistive element of a first embodiment.

FIGS. 2A and 2B are diagrams showing the principle of heat production in a heat producing layer.

FIG. 3 is a diagram showing an application example of the first embodiment.

FIG. 4 is a diagram showing the principle of crystallization in the application example of FIG. 3.

FIG. 5 is an explanatory diagram showing an improvement in an MR ratio.

FIG. 6 is a diagram showing the relationship between coercivity and an MR ratio.

FIG. 7 is a diagram showing a magnetoresistive element of a second embodiment.

FIG. 8 is a diagram showing an application example of the second embodiment.

FIG. 9 is a diagram showing the principle of crystallization in the application example of FIG. 7.

FIG. 10 is a diagram showing an MRAM as a memory device.

FIG. 11 is a diagram showing a memory cell of the MRAM.

FIG. 12 is a cross-sectional view taken along line XII-XII of FIG. 11.

FIG. 13 is a cross-sectional view taken along line XIII-XIII of FIG. 11.

FIGS. 14 and 15 are diagrams showing a method of manufacturing the MRAM shown in FIGS. 11 to 13.

FIG. 16 is a diagram showing an example of a nonvolatile cache system.

### DETAILED DESCRIPTION

In general, according to one embodiment, a magnetoresistive element comprises: a first magnetic layer; an insulating layer on the first magnetic layer; a second magnetic layer on the insulating layer; and an aluminum boride layer on the second magnetic layer.

### 1. Magnetoresistive Element

### (1) First Embodiment

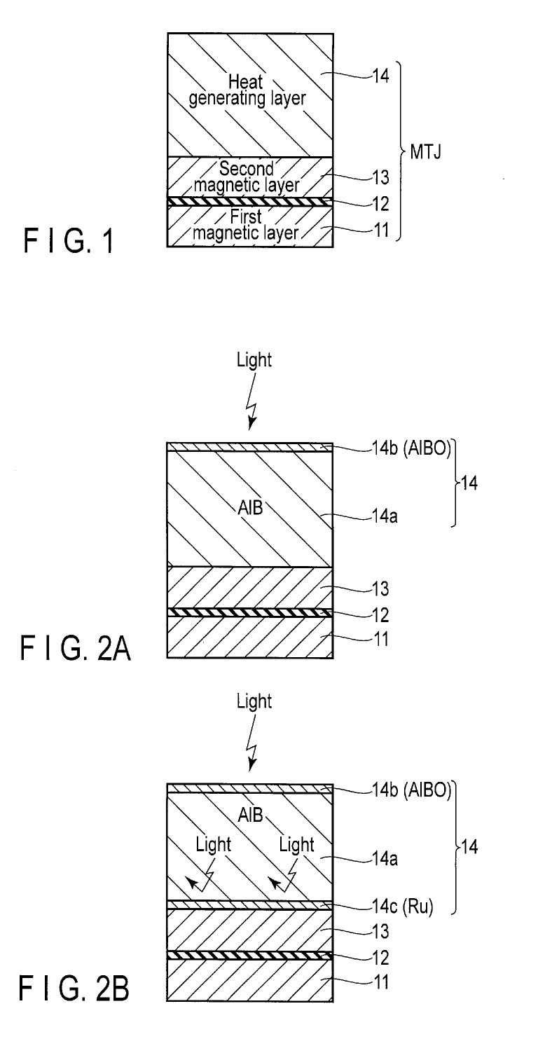

FIG. 1 is a diagram showing a magnetoresistive element of a first embodiment.

A magnetoresistive element MTJ comprises a first magnetic layer 11, an insulating layer 12 on the first magnetic layer 11, a second magnetic layer 13 on the insulating layer 12, and a heat producing layer 14 on the second magnetic layer 13.

Among the first and second magnetic layers 11 and 13, one is a reference layer having fixed magnetization and the other is a storage layer having variable magnetization.

Here, the fixed magnetization means that the direction of magnetization does not change between before and after a write operation, and the variable magnetization means that the direction of magnetization is reversible between before and after a write operation.

Further, the write operation means a spin transfer write operation performed by passing spin injection current (spin-polarized electrons) through the magnetoresistive element MTJ and applying spin torque to the magnetization of the storage layer.

If the first magnetic layer 11 is a storage layer and the second magnetic layer 13 is a reference layer, the magnetoresistive element MTJ is of a top-pin type. Further, if the first magnetic layer 11 is a reference layer and the second magnetic layer 13 is a storage layer, the magnetoresistive element MTJ is of a bottom-pin type.

It is desirable that each of the first and second magnetic layers 11 and 13 should have perpendicular magnetization, that is, perpendicular residual magnetization the direction of which is the laminating direction of the first and second magnetic layers 11 and 13. Note that each of the first and second magnetic layers 11 and 13 may have in-plane magnetization, that is, in-plane residual magnetization the direction of which is perpendicular to the laminating direction of the first and second magnetic layers 11 and 13.

The resistance of the magnetoresistive element MTJ varies depending on the relationship of the directions of magnetization of the storage layer and the reference layer due to a magnetoresistive effect. For example, the resistance of the magnetoresistive element MTJ becomes low when the directions of magnetization of the storage layer and the reference layer are the same, that is, in parallel, and becomes high when the directions of magnetization of the storage layer and the reference layer are opposite to each other, that is, in antiparallel.

The first and second magnetic layers 11 and 13 contain, for example, CoFeB, MgFeO, or the like.

In the case of the magnetoresistive element MTJ having perpendicular magnetization, it is desirable that the first and second magnetic layers 11 and 13 should contain TbCoFe having perpendicular magnetic anisotropy, have an artificial lattice of laminated Co and Pt, contain L10 ordered FePt, or the like. In that case, it is desirable that CoFeB as an interface layer be interposed between the first magnetic layer 11 and the insulating layer 12 and between the insulating layer 12 and the second magnetic layer 13.

The insulating layer 12 contains, for example, MgO, Al, or the like. The insulating layer 12 may be an oxide of Al, Si, Be, Mg, Ca, Sr, Ba, Sc, Y, La, Zr, Hf or the like. In the case of using MgO for the insulating layer 12, the thickness is set to be 1 nm or so due to the limitation of resistance.

The heat producing layer 14 crystallizes the first and second magnetic layers 11 and 13 and the insulating layer 12 and functions as a heat source to form heteroepitaxial bonded interfaces between the first and second magnetic layers 11 and 13 and the insulating layer 12.

The heat producing layer 14 is provided in proximity to the first and second magnetic layers 11 and 13. In crystallizing the first and second magnetic layers 11 and 13, therefore, the heat produced in the heat producing layer 14 is transmitted efficiently to the first and second magnetic layers 11 and 13.

Further, it is desirable that the heat producing layer 14 be formed of a material suitable for high-temperature heat treatment for a short period of time. This is because high-temperature, short-time heat treatment can suppress unnecessary diffusion of the elements contained in the first and second magnetic layers 11 and 13 into the interfaces between the first and second magnetic layers 11 and 13 and the insulating layer 12 and an excellent bonded interface can be formed.

For example, a material having a band gap of 1 eV or less can be used as the material for the heat producing layer 14. Such a material quickly absorbs the light in a heat treatment method such as rapid heat annealing (RTA). That is, since a material having a band gap of 1 eV or less produces high-temperature heat in a short time, it is possible to transmit the heat to the first and second magnetic layers 11 and 13.

Now, a case in which the heat producing layer 14 is aluminum boride, for example, AlB will be described.

As shown in FIG. 2A, when AlB 14a is exposed to air, the AlB 14a is partly changed to AlBO 14b and this creates a band gap of 1 eV or less between the AlB 14a and the AlBO 14b. If RTA is performed in this state for example, the light from a lamp is absorbed and converted into heat. Therefore, it is possible to efficiently produce heat in the heat producing layer 14 to perform high-temperature, short-time heat treatment.

Further, as shown in FIG. 2B, the heat producing layer 14 may comprise a light reflection layer (of, for example, Ru) 14c. In that case, since the light for the heat treatment is reflected in the light reflection layer 14c, it becomes possible to produce heat more efficiently in the heat producing layer 14.

The heat produced in the heat producing layer 14 is transmitted to the first and second magnetic layers 11 and 13 and the insulating layer 12 at a speed of the order of nano seconds. Further, the heat transmitted to the first and second magnetic layers 11 and 13 and the insulating layer 12 is transmitted to an electrode, a semiconductor substrate provided immediately below at a speed of the similar order. That is, it takes the order of nano seconds to apply the high-temperature heat to the first and second magnetic layers 11 and 13. In this way, high-speed heating and high-speed cooling can be achieved.

Note that, when each of the first and second magnetic layers 11 and 13 contains CoFeB and the insulating layer 12 contains MgO and if the above-described high-temperature, short-time heat treatment is performed thereon, each of the first and second magnetic layer 11 and 13 changes from an amorphous state to a state of having the BCC crystal structure in which the film surfaces are oriented in the (001) plane.

Note that the insulating layer 12 is assumed to have a NaCl-type crystal structure in which the film surfaces are oriented in the (001) plane. Further, the film surfaces are assumed to be the interfaces between the first and second magnetic layer 11 and 13 and the insulating layer 12.

Further, it is desirable that the heat producing layer 14 be heated by light having a wavelength of 1100 nm or more.

This is for performing high-speed cooling on the first and second magnetic layers 11 and 13 and the insulating layer 12. For example, as described above, when the heat transmitted to the first and second magnetic layers 11 and 13 and the insulating layer 12 is to be released to a semiconductor substrate (for example, a silicon substrate) and if the substrate has been heated, it is difficult to cool the first and second magnetic layers 11 and 13 and the insulating layer 12 quickly.

If the heat treatment is performed by light having such a wavelength as to heat the first and second magnetic layers 11 and 13 and as not to heat the semiconductor substrate, that is, a wavelength of 1100 nm or more, it becomes possible to perform high-speed heating and high-speed cooling by using the heat produced in the heat producing layer 14.

Note that, for example, the layer formed at the interface between the AlB 14a and the AlBO 14b absorbs light having a wavelength of 1100 nm or more and thus is heated efficiently by the light. On the other hand, the silicon substrate allows light having a wavelength of 1100 nm or more to pass thorough and thus is hardly heated by the light.

The heat producing layer 14 may function as a hard mask layer for patterning the first magnetic layer 11, the insulating layer 12 and the second magnetic layer 13. In that case, it is desirable that the heat producing layer 14 should further meet the following requirements:

(1) It can be easily patterned by RIE;

(2) It exhibits high etching resistance (milling resistance) as a mask; and

(3) Variations in the above (1) and (2) are small.

Aluminum boride typically used for the heat producing layer 14 is more volatile as compared to Ta or HfB used for conventional hard masks because of gaseous halogen, and therefore it can be said that aluminum boride can be easily patterned by RIE.

Further, it suffices the heat producing layer 14 is formed of a material having the characteristics (1) to (3) and capable of producing heat by absorbing light. For example, TiB, ZrB, AlC, TiC or ZrC, or a composite thereof may be used for the heat producing layer 14.

Still further, when aluminum boride typically used for the heat producing layer 14 is used as a mask and the first magnetic layer 11, the insulating layer 12 and the second magnetic layer 13 are patterned by milling using non-volatile gas (for example, Ar ions), aluminum boride exhibits etching resistance (milling resistance) to Ar ion milling four times higher than Ta typically used for conventional hard mask layers.

That is, it can be said that aluminum boride exhibits high etching resistance (milling resistance) as a mask.

Still further, if gaseous Kr or Xe heavier than that of Ar is used as the etching gas obtained by ion milling, the etching speed of Tb or Pt used for the first and second magnetic layers 11 and 13 increases while the etching speed of AlB decreases. As a result, the characteristics (2) improve, and thus it becomes possible to perform patterning of electromagnetic elements with small variations.

Still further, it is possible to make aluminum boride typically used for the heat producing layer 14 amorphous by optimizing the composition ratio, that is, the content of boron (B). Note that it is desirable that the concentration of B be in a range of 20 to 60 atomic %. It is because the characteristics (1) deteriorate when the concentration of B is 60 atomic % or more. It is also because the characteristics (2) and (3) deteriorate when the concentration of B is 20 atomic % or less. Further, it is desirable that the concentration of B be in the above-described range also in light of controlling of the band gap.

Further, aluminum boride in an amorphous state does not exhibit variations in patterning accuracy and etching resistance which are caused by crystal grains developed in aluminum boride in a crystalline state.

Therefore, it can be said for aluminum boride that variations in patterning accuracy by RIE and in etching resistance as a mask are small.

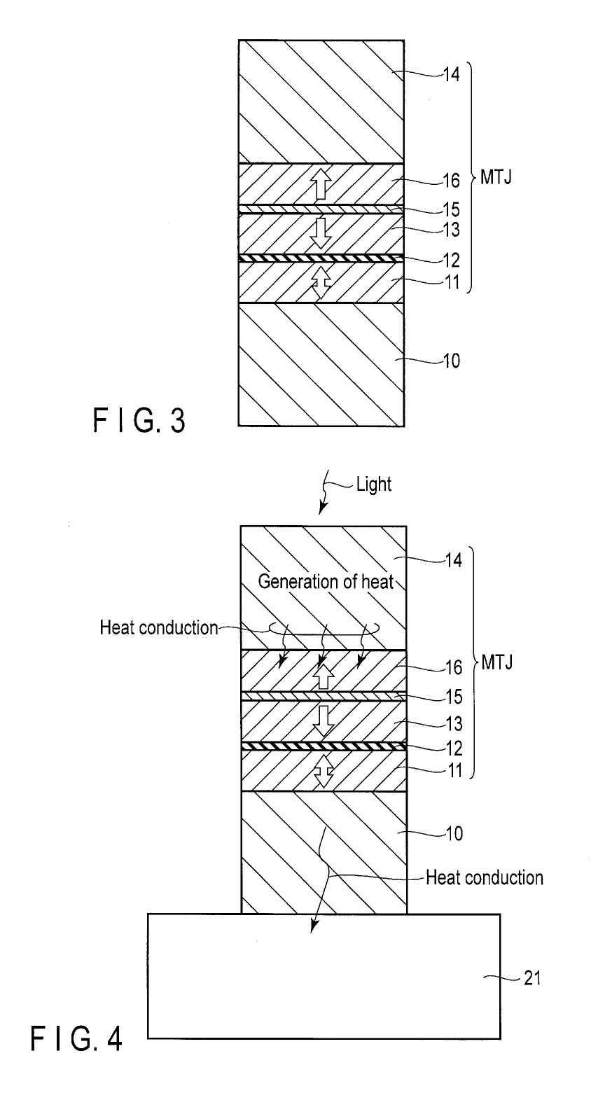

FIG. 3 is a diagram showing an application example of the first embodiment.

The electrode 10 contains, for example, one of Al, Be, Mg, Ca, Sr, Ba, Sc, Y, La, Ti, Zr and Hf or an alloy thereof.

The first magnetic layer 11 is a storage layer and provided on the electrode 10. The insulating layer 12 is provided on the first magnetic layer 11. The second magnetic layer 13 is a reference layer and provided on the insulating layer 12. A nonmagnetic metal layer 15 is provided on the second magnetic layer 13. The nonmagnetic metal layer 15 contains, for example, Pt, Ta, Ru or the like. A third magnetic layer 16 is provided on the nonmagnetic metal layer 15.

The third magnetic layer 16 functions as the so-called shift canceling layer. The shift canceling layer is magnetized in a direction opposite to the direction of magnetization of the reference layer. Therefore, the shift canceling layer cancels the shift of the magnetization reversal characteristics (the hysteresis curve) of the storage layer caused by the magnetic stray field from the reference layer. The shift canceling layer has, for example, a laminated structure [Co/Pt]n with n layers of a Co layer and a Pt layer.

The heat producing layer 14 is provided on the third magnetic layer 16.

FIG. 4 is a diagram showing the principle of crystallization in the application example of FIG. 3.

In FIG. 4, the components the same as those of FIG. 3 are denoted by the same reference numbers and symbols, and the descriptions thereof are omitted.

The heat producing layer 14 produces heat, for example, when receiving light from a lamp used for RTA. The heat is transmitted to the first and second magnetic layers 11 and 13 and the insulating layer 12 by heat conductance. Therefore, the first and second magnetic layers 11 and 13 and the insulating layer 12 are crystallized by an annealing effect.

Further, the heat produced in the heat producing layer 14 is transmitted to the electrode 10 and further to the semiconductor substrate 21 through the first, second and third magnetic layers 11, 13 and 16.

Here, by setting the wavelength of the light to be 1100 nm or more, it is possible to heat the heat producing layer 14 selectively and not to heat the semiconductor substrate 21 as described above.

Therefore, it is possible in crystallization of the first and second magnetic layers 11 and 13 and the insulating layer 12 to perform high-speed heating and high-speed cooling and to prevent unnecessary diffusion of elements contained in the first and second magnetic layers 11 and 13. That is, an excellent bonded interface can be formed to achieve an improvement in the MR ratio of a magnetoresistive element MTJ.

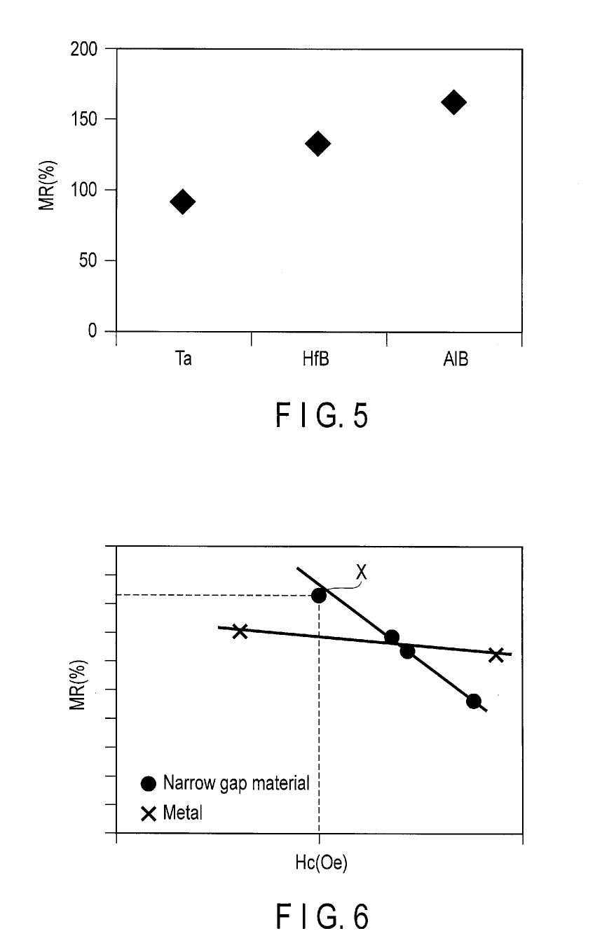

FIG. 5 is an explanatory diagram showing an improvement in the MR ratio.

The drawing shows the comparison in the structure of FIG. 4 between the MR ratio (comparative example) obtained when RTA is performed in a state of using a conventional hard mask layer (Ta or HfB) in place of the heat producing layer 14 and the MR ratio (embodiment) obtained when RTA is performed in a state of using AlB as the heat producing layer 14.

That is, the only difference between the comparative example and the embodiment is whether to use the heat producing layer 14 or a conventional hard mask layer in place of the heat producing layer 14.

According to the drawing, the MR ratio is maximum when the heat producing layer (AlB) 14 is used. It shows that the heat producing layer 14 achieves high-temperature, short-time heat treatment on the first and second magnetic layers 11 and 13 and the insulating layer 12.

FIG. 6 is a diagram showing the relationship between coercivity and an MR ratio.

The drawing shows the comparison in the structure of FIG. 4 between the relationship (comparative example) between the coercivity Hc and the MR ratio obtained when RTA is performed in a state of using a conventional hard mask layer (of metal such as Ta) in place of the heat producing layer 14 and the relationship (embodiment) between the coercivity Hc and the MR ratio obtained when RTA is performed in a state of using a material having a band gap of 1 eV or less for the heat producing layer 14.

According to the drawing, the case of AlB is indicated by point X. That is, if AlB is used as the heat producing layer 14, it is possible to achieve both a high MR ratio and high coercivity Hc. This means that unnecessary diffusion of elements in the first and second magnetic layers 11 and 13 has been prevented by the high-temperature, short-time heat treatment on the first and second magnetic layers 11 and 13.

As described above, according to the first embodiment, it is possible to perform high-temperature, short-time heat treatment by using a material having a band gap of 1 eV or less for the heat producing layer 14 such as aluminum boride. In this way, an excellent bonded interface can be formed to achieve an improvement in the MR ratio of a magnetoresistive element MTJ by a spin filter effect.

### (2) Second Embodiment

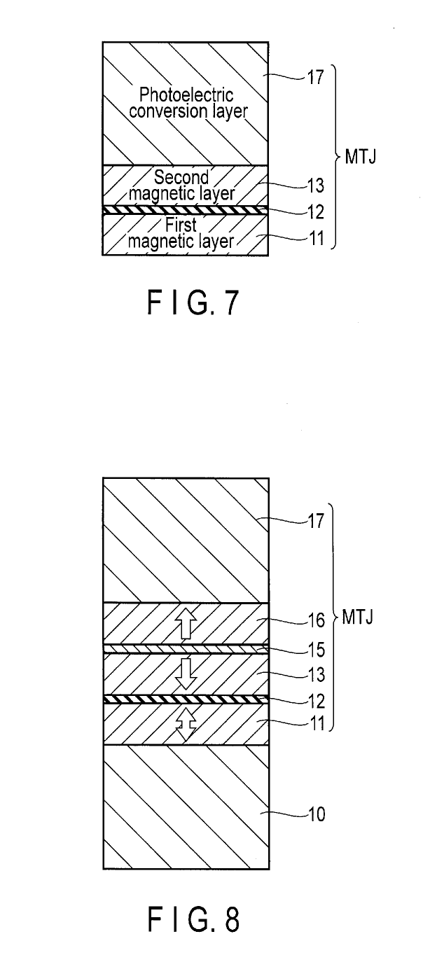

FIG. 7 is a diagram showing a magnetoresistive element of a second embodiment.

A magnetoresistive element MTJ comprises a first magnetic layer 11, an insulating layer 12 on the first magnetic layer 12, a second magnetic layer 13 on the insulating layer 12, and a photoelectric conversion layer 17 on the second magnetic layer 13. The photoelectric conversion layer 17 is a layer capable of producing heat and a voltage from light and comprises, for example, a pn junction of a p-type semiconductor layer and an n-type semiconductor layer.

The photoelectric conversion layer 17 produces an effect the same as that produced in the heat producing layer 14 of FIG. 1 (first embodiment). That is, the first and second magnetic layers 11 and 13 are crystallized by heat produced in the photoelectric conversion layer 17. In the crystallization, since unnecessary diffusion of elements is prevented in a manner similar to that of the first embodiment, it becomes possible to achieve an improvement in the MR ratio.

Note that the first magnetic layer 11, the insulating layer 12 and the second magnetic layer 13 are the same as those of the first embodiment, and thus the descriptions thereof are omitted.

FIG. 8 is a diagram showing an application example of the second embodiment.

The electrode 10 contains, for example, one of Al, Be, Mg, Ca, Sr, Ba, Sc, Y, La, Ti, Zr and Hf or an alloy thereof.

The first magnetic layer 11 is a storage layer and provided on the electrode 10. The insulating layer 12 is provided on the first magnetic layer 11. The second magnetic layer 13 is a reference layer and provided on the insulating layer 12. A nonmagnetic metal layer 15 is provided on the second magnetic layer 13. The nonmagnetic metal layer 15 contains, for example, Pt, Ta, Ru or the like. A third magnetic layer 16 is provided on the nonmagnetic metal layer 15.

The third magnetic layer 16 functions as the so-called shift canceling layer. The shift canceling layer is magnetized in a direction opposite to the direction of magnetization of the reference layer. Therefore, the shift canceling layer cancels the shift of the magnetization reversal characteristics (the hysteresis curve) of the storage layer caused by the magnetic stray field from the reference layer. The shift canceling layer has, for example, a laminated structure [Co/Pt]n with n layers of a Co layer and a Pt layer.

The photoelectric conversion layer 17 is provided on the third magnetic layer 16.

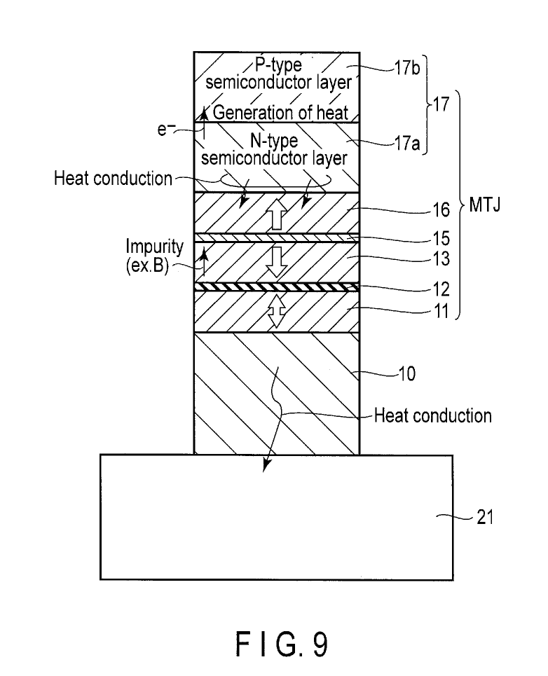

FIG. 9 is a diagram showing the principle of crystallization in the application example of FIG. 8.

In FIG. 9, the components the same as those of FIG. 8 are denoted by the same reference numbers and symbols, and the descriptions thereof are omitted.

The photoelectric conversion layer 17 comprises an n-type semiconductor layer 17a and a p-type semiconductor 17b.

The photoelectric conversion layer 17 produces heat, for example, when receiving light from a lamp used for RTA. The heat is transmitted to the first, second and third magnetic layers 11, 13 and 16 by heat conductance. Further, the photoelectric conversion layer 17 produces a voltage, for example, when receiving light from the lamp used for RTA. The voltage attracts impurities contained in the second magnetic layer 13.

For example, when the second magnetic layer 13 contains CoFeB, boron (B) in the second magnetic layer 13 is attracted to the photoelectric conversion layer 17.

As a result, for example, the concentration of boron in the second magnetic layer (CoFeB) decreases, and thus the crystallization temperature of the second magnetic layer 13 decreases. That is, the crystallization of the second magnetic layer 13 is encouraged (electric field assisted effect).

Further, the heat produced in the photoelectric conversion layer 17 is transmitted to the electrode 10 and further to the semiconductor substrate 21 through the first, second and third magnetic layers 11, 13 and 16.

Here, by setting the wavelength of the light to be 1100 nm or more, it is possible to heat the photoelectric conversion layer 17 selectively and not to heat the semiconductor substrate 21.

Therefore, it is possible in crystallization of the first and second magnetic layers 11 and 13 and the insulating layer 12 to perform high-speed heating and high-speed cooling and to prevent unnecessary diffusion of elements contained in the first and second magnetic layers 11 and 13. That is, an excellent bonded interface can be formed to achieve an improvement in the MR ratio of a magnetoresistive element MTJ.

Note that the light used for producing heat in the photoelectric conversion layer 17 and the light used for producing a voltage in the photoelectric conversion layer 17 may be the same (may have the same wavelength) or may be different from each other (may have wavelengths different from each other).

As described above, according to the second embodiment, it is possible with the photoelectric conversion layer 17 to crystallize the first and second magnetic layers 11 and 13 by performing thereon high-temperature, short-time heat treatment and providing therewith electric field assist in encouraging crystallization. In this way, an excellent bonded interface can be formed to achieve an improvement in the MR ratio of a magnetoresistive element MTJ by a spin filter effect.

### 2. Memory Device

An example of a memory device comprising the magnetoresistive element of the first or second embodiment will be described.

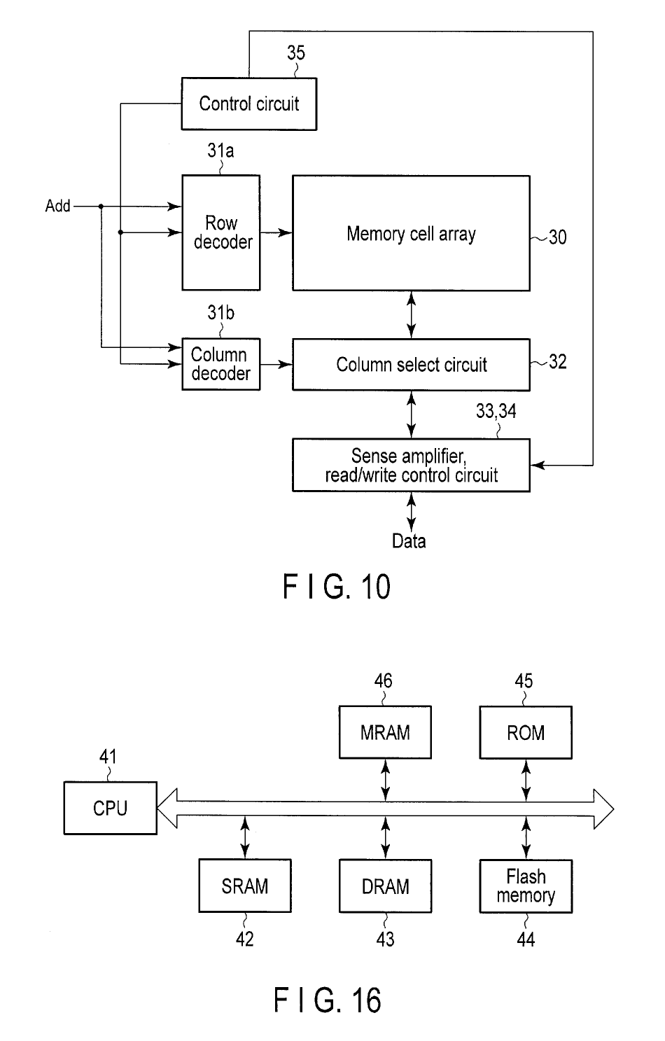

FIG. 10 is a diagram showing an MRAM as a memory device.

A memory cell array 30 comprises a plurality of memory cells. A row decoder 31a and a column decoder 31b perform random access to one of the plurality of memory cells in the memory cell array 30 based on an address signal Add.

A column select circuit 32 is configured to electrically connect the memory cell array 30 and a sense amplifier 33 based on a signal from the column decoder 31b.

A read/write control circuit 34 is configured in a read operation to supply a read current to a memory cell selected in the memory cell array 30. The sense amplifier 33 is configured to determine data stored in the selected memory cell by detecting the read current.

Further, the read/write control circuit 34 is configured in a write operation to supply a write current to the memory cell selected in the memory cell array 30, thereby writing data in the selected memory cell.

A control circuit 35 is configured to control the operations of the row decoder 31a, the column decoder 31b, the sense amplifier 33, and the read/write control circuit 34.

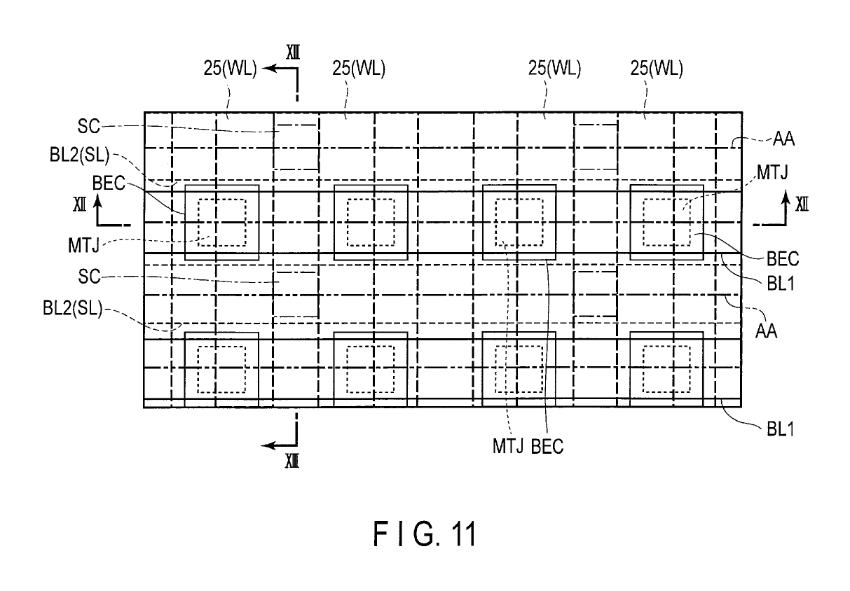

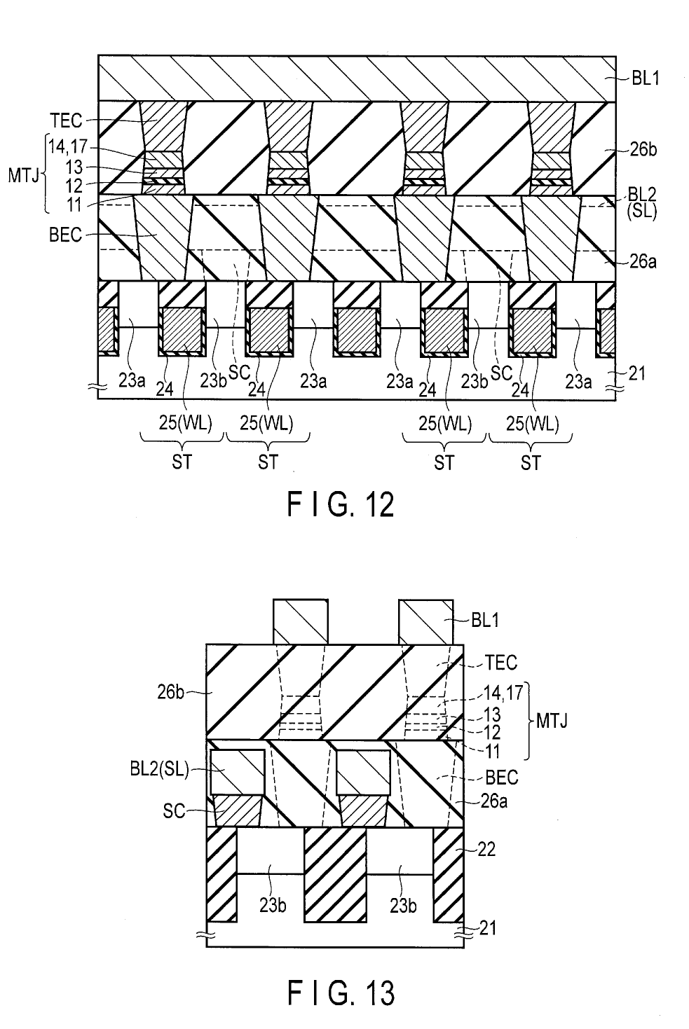

FIGS. 11 to 13 are diagrams showing MRAM memory cells. FIG. 11 is a plan view of MRAM memory cells, FIG. 12 is a cross-sectional view take along line XII-XII of FIG. 11, and FIG. 13 is a cross-sectional view taken along line XIII-XIII of FIG. 11.

In the present example, the memory cell of the magnetic memory comprises a select transistor (for example, an FET) ST and a magnetoresistive element MTJ.

The select transistor ST is provided in an active area AA in the semiconductor substrate 21. The active area AA is surrounded by an element isolation insulating layer 22 in the semiconductor substrate 21. In the present example, the element isolation insulating layer 22 has a shallow trench isolation (STI) structure.

The select transistor ST comprises source/drain diffusion layers 23a and 23b in the semiconductor substrate 21, and further comprises therebetween a gate insulating layer 24 and a gate electrode (word line) 25 formed in the semiconductor substrate 21. The select transistor ST of the present example has the so-called buried-gate structure in which the gate electrode 25 is buried in the semiconductor substrate 21.

An interlayer insulating layer (for example, oxide silicon layer) 26a covers the select transistor ST. Contact plugs BEC and SC are provided in the interlayer insulating layer 26a. Contact plug BEC is connected to source/drain diffusion layer 23a, and contact plug SC is connected to source/drain diffusion layer 23b. Contact plugs BEC and SC contain, for example, one of W, Ta, Ru and Ti.

A magnetoresistive element MTJ is provided on contact plug BEC. The magnetoresistive element MTJ comprises, a first magnetic layer 11, an insulating layer 12, a second magnetic layer 13, and a heat producing layer 14 (corresponding to the first embodiment) or the first magnetic layer 11, the insulating layer 12, the second magnetic layer 13 and a photoelectric conversion layer 17 (corresponding to the second embodiment).

A contact plug TEC is provided on the magnetoresistive element MTJ. The interlayer insulating layer (for example, oxide silicon layer) 26b covers the magnetoresistive element MTJ.

A bit line BL1 is connected to the magnetoresistive element MTJ via contact plug TEC. A bit line BL2 is connected to source/drain diffusion layer 23b via contact plug SC. Bit line BL2 also functions, for example, in a read operation as a source line to which ground voltage is applied.

### 3. Manufacturing Method

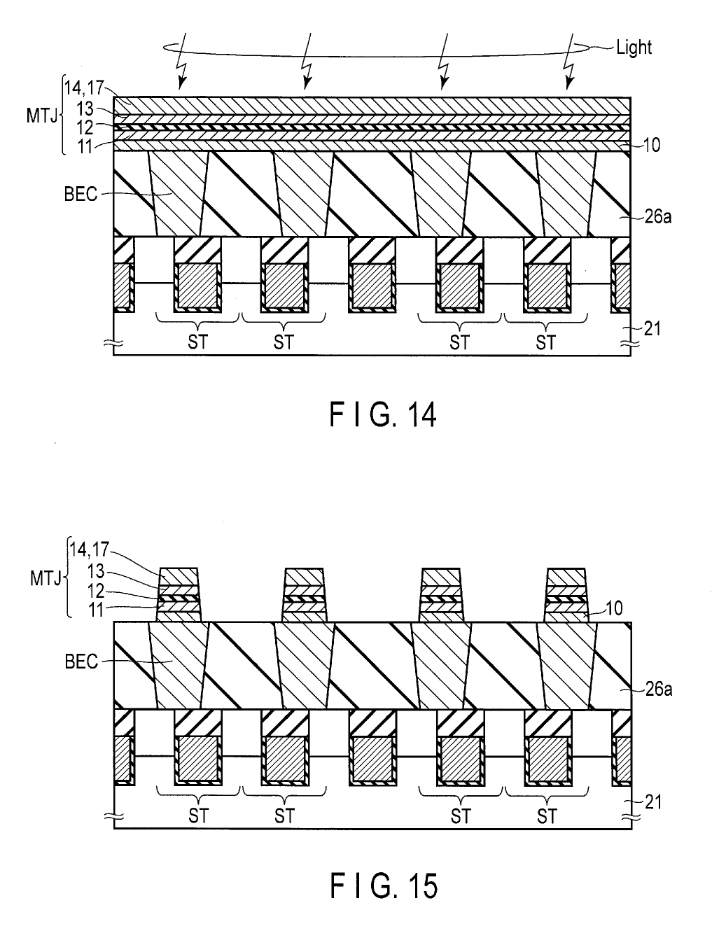

FIGS. 14 and 15 are diagrams showing a method of manufacturing the MRAM of FIGS. 11 to 13.

First, as shown in FIG. 14, the select transistor ST having the buried-gate structure is formed in the semiconductor substrate 21. Further, the interlayer insulating layer 26a is formed, and contact plug BEC is then formed in the interlayer insulating layer 26a.

Subsequently, on the interlayer insulating layer 26a and contact plug BEC, a laminated structure of the electrode 10 having an amorphous state, the first magnetic layer 11 having an amorphous state, the insulating layer 12, the second magnetic layer 13 having an amorphous state, and the heat producing layer 14 (or photoelectric conversion layer 17) is formed.

The heat producing layer 14 (or photoelectric conversion layer 17) is then irradiated with light from a lamp as a light source to crystallize the first and second magnetic layers 11 and 13 and the insulating layer 12.

At this time, by irradiating with light having a wavelength of 1100 nm or more, it is possible to heat the heat producing layer 14 (or photoelectric conversion layer 17) selectively and not to heat the semiconductor substrate 21.

Next, as shown in FIG. 15, the heat producing layer 14 (or photoelectric conversion layer 17) is patterned by a photoengraving process (PEP) or an RIE process. Further, this layer is used as a hard mask layer to pattern the first magnetic layer 11, the insulating layer 12, the second magnetic layer 13 and the electrode 10 by physical etching such as ion beam etching (IBE).

Subsequently, as shown in FIG. 12, components such as the interlayer insulating layer 26b, contact plug TEC and bit line BL1 are formed, and the MRAM of FIGS. 11 to 13 is then complete.

### 4. Application Example

Processors used for personal digital assistances are required to operate on low power. There is a method of reducing energy consumption of the processor by replacing a static random access memory (SRAM) based cache memory having high standby power consumption with a nonvolatile semiconductor memory using a nonvolatile element.

That is, in the SRMA, the amount of leakage power tends to increase both in operation and on standby (not in operation) as transistors are miniaturized. By replacing the cache memory with the nonvolatile semiconductor memory, it becomes possible to cut off power on standby and to reduce power consumption on standby.

It is possible to realize a low-power consumption processer, for example, by using the above-described magnetic random access memory (MRAM) as the cache memory.

FIG. 16 is a diagram showing a low-power consumption processer system.

A CPU 41 is configured to control an SRAM 42, a DRAM 43, a flash memory 44, a ROM 45 and a magnetic random access memory (MRAM) 46.

The MRAM 46 may be used as a substitute for any of the SRAM 42, the DRAM 43, the flash memory 44, and the ROM 45. Further, at least one of the SRAM 42, the DRAM 43, the flash memory 44 and the ROM 45 may be omitted.

The MRAM 46 may be used as a nonvolatile cache memory (for example, an L2 cache).

### 5. Conclusion

As described above, according to the embodiments, an excellent bonded interface can be formed to achieve an improvement in the MR ratio of a magnetoresistive element MTJ by a spin filter effect.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistive element comprising:
a first magnetic layer;
an insulating layer on the first magnetic layer;
a second magnetic layer on the insulating layer; and
an aluminum boride layer on the second magnetic layer.

2. The element of claim 1, wherein the aluminum boride layer contains AlB, and a concentration of B in AlB is 20 atomic % or more and 60 atomic % or less.

3. The element of claim 1, wherein each of the first and second magnetic layers contains Co and Fe and the insulating layer contains MgO.

4. The element of claim 3, wherein
each of the first and second magnetic layers has a BCC crystal structure in which film surfaces are orientated in a (001) plane, and
the insulating layer has a NaCl-type crystal structure in which film surfaces are orientated in the (001) plane.

5. The element of claim 1, wherein
the aluminum boride layer produces heat from light having a wavelength of 1100 nm or more.

6. The element of claim 1, wherein
the aluminum boride layer has an amorphous state.

7. A magnetoresistive element comprising:
a first magnetic layer;
an insulating layer on the first magnetic layer;
a second magnetic layer on the insulating layer; and
a heat producing layer on the second magnetic layer, the heat producing layer having a band gap of 1 eV or less.

8. The element of claim 7, wherein
the heat producing layer contains at least one of AlB, TiB, ZrB, AlC, TiC and ZrC.

9. The element of claim 7, wherein
each of the first and second magnetic layers contains Co and Fe and the insulating layer contains MgO.

10. The element of claim 9, wherein
each of the first and second magnetic layers has a BCC crystal structure in which film surfaces are orientated in a (001) plane, and
the insulating layer has a NaCl-type crystal structure in which film surfaces are orientated in the (001) plane.

11. The element of claim 7, wherein the heat producing layer produces heat from light having a wavelength of 1100 nm or more.

12. The element of claim 7, wherein the heat producing layer has an amorphous state.

13. A magnetoresistive element comprising:
a first magnetic layer;
an insulating layer on the first magnetic layer;
a second magnetic layer on the insulating layer; and
a photoelectric conversion layer on the second magnetic layer.

14. The element of claim 13, wherein
the photoelectric conversion layer comprises a pn-junction of a p-type semiconductor layer and a n-type semiconductor layer.

15. The element of claim 13, wherein
each of the first and second magnetic layers contains Co and Fe and the insulating layer contains MgO.

16. The element of claim 15, wherein
each of the first and second magnetic layers has a BCC crystal structure in which film surfaces are orientated in a (001) plane, and
the insulating layer has a NaCl-type crystal structure in which film surfaces are orientated in the (001) plane.

17. The element of claim 13, wherein
the photoelectric conversion layer produces heat from first light having a wavelength of 1100 nm or more.

18. The element of claim 17, wherein
the photoelectric conversion layer produces a voltage from second light having a wavelength of 1100 nm or more.

19. The element of claim 18, wherein the first light and the second light have the same wavelength.

20. A method of manufacturing the element of claim 1, the method comprising:
forming a laminated structure of the first magnetic layer having an amorphous state, the insulating layer, the second magnetic layer having an amorphous state, and the aluminum boride layer; and
crystallizing the first and second magnetic layers by irradiating the aluminum boride layer with light having a wavelength of 1100 nm or more.

21. A method of manufacturing the element of claim 7, the method comprising:
forming a laminated structure of the first magnetic layer having an amorphous state, the insulating layer, the second magnetic layer having an amorphous state, and the heat producing layer; and
crystallizing the first and second magnetic layer by irradiating the heat producing layer with light having a wavelength of 1100 nm or more.

22. A method of manufacturing the element of claim 13, the method comprising:
forming a laminated structure of the first magnetic layer having an amorphous state, the insulating layer, the second magnetic layer having an amorphous state, and the photoelectric conversion layer; and
crystallizing the first and second magnetic layer by irradiating the photoelectric conversion layer with light having a wavelength of 1100 nm or more.

23. A memory device comprising:
a semiconductor substrate;
a select transistor on the semiconductor substrate; and
the element of claim 1 above the select transistor, the element connected to the select transistor.

24. A memory device comprising:
a semiconductor substrate;
a select transistor on the semiconductor substrate; and
the element of claim 7 above the select transistor, the element connected to the select transistor.

25. A memory device comprising:
a semiconductor substrate;
a select transistor on the semiconductor substrate; and
the element of claim 13 above the select transistor, the element connected to the select transistor.
